(19) United States
(12) Patent Application Publication
(10) Pub. No.: US 2022/0311207 A1
(43) Pub. Date: Sep. 29, 2022

(54) Transistor outline packaged laser diode and heat dissipation base thereof

(71) Applicant: EZCONN CORPORATION, New Taipei City (TW)

(72) Inventor: Chin-Tsung Wu, New Taipei City (TW)

(21) Appl. No.: 17/698,256

(22) Filed: Mar. 18, 2022

(30) Foreign Application Priority Data
Mar. 23, 2021 (TW) 110203081

(51) Int. Cl. H01S 5/024; H01S 5/02212

(52) U.S. Cl. CPC H01S 5/02415; H01S 5/02212

(57) ABSTRACT

A heat dissipation base is suitable for a transistor outline packaged laser diode. The heat dissipation base includes a basal wall and a heat dissipation wall extending outward from one side of the basal wall, the side surface of the basal wall defines a can-shaped packaging area. The heat dissipation wall is located in the packaging area and has a bearing surface. The heat dissipation base further includes an extension wall extending outward from the other side of the basal wall, the basal wall, the heat dissipation wall, and the extension wall are integrated, and the extension wall includes a primary cooling surface for in contact with an external heat dissipation element. The present invention also provides a transistor outline packaged laser diode using the above-mentioned heat dissipation base.

### RELATED APPLICATIONS

This application claims priority to TW Application Ser. No. TW 110203081, filed on Mar. 23, 2021, which is incorporated herein by reference in its entirety.

### TECHNICAL FIELD

The present invention is related to a laser diode and base thereof, especially, related to a transistor outline packaged laser diode and heat dissipation base thereof which can provide stable placement and improve the heat dissipation capability.

### BACKGROUND

There are three major types of package structure for laser diodes: dual in-line package referred to as DIP, butterfly package and transistor outline package referred to as TO package. The housing typically used in the DIP package is usually a cuboid, which is currently mainly used in telecommunication, common-antenna Television referred to as CATV, local area network referred to as LAN or optical time domain reflectometer referred to as OTDR and so on.

The pins of the DIP package are perpendicular to the horizontal direction of the housing. Similar to a DIP package, the butterfly package has pins that are parallel to the horizontal direction of the housing, which enables faster transmission in circuits. TO package features small size, which makes it difficult to realize heat dissipation technologies internal to the package; therefore, heat dissipation is an urgent problem to be solved.

With the development of high-frequency transmission technology, electronic components tend to generate a large amount of heat under high-frequency transmission conditions. Due to the heat accumulation of laser diode during operation, hot spots will form, which will increase the temperature of the laser diode, causing spectrum drift and power loss, and even worse, the laser diode may become damaged.

The current TO-CAN laser diode has a disc-shaped basal wall and a heat dissipation wall extending outward from one side of the basal wall. The laser sub-assembly is located on the heat dissipation wall. To use the current TO-CAN laser diode, the lower half of the TO-CAN laser diode's basal wall must be mounted on a bracket with a semi-arc peripheral surface first, and then placed on an external heat dissipation element (such as a heat sink). Since the basal wall and the bracket cannot be in close contact on the engaging surface, during operation, heat generated by the laser diode must be transferred to the external heat dissipation element by applying thermal paste between the basal wall and the bracket, which ensures that the heat dissipation path remains unobstructed. Heat dissipation is influenced by the thickness or uniformity of the thermal paste coating, and the width of the basal wall along the axial direction is small, that is, the bracket and the basal wall have a limited engaging area so that the heat cannot be effectively transferred to the outside. The current TO-CAN laser diodes must be improved.

### SUMMARY

The purpose of the present invention is to provide a transistor outline packaged laser diode that can enhance the effectiveness of heat dissipation.

The present invention provides a transistor outline packaged laser diode, comprising a heat dissipation base, a thermoelectric cooler, a laser sub-assembly, and a cover. The heat dissipation base includes a basal wall, a heat dissipation wall, and an extension wall. A side surface of the basal wall defines a packaging area. The heat dissipation wall extends outward from the side of the basal wall and has a bearing surface located in the packaging area. The extension wall extends outward from the other side surface of the basal wall and has a primary cooling surface for contacting an external heat dissipation element, wherein the basal wall, the heat dissipation wall and the extension wall are integrated.

The thermoelectric cooler is mounted on the bearing surface of the heat dissipation wall. The laser sub-assembly is mounted on the thermoelectric cooler and electrically connected to the thermoelectric cooler. The cover is hollow and includes a first end portion and a second end portion, wherein the peripheral edge of the first end portion corresponds to the peripheral edge of the packaging area and the second end portion defines an accommodating space.

In some embodiments, the thermoelectric cooler defines a first width, the heat dissipation wall defines a second width, the first width over the second width is ranging from 0.8 to 1.

In some embodiments, the center of gravity of the heat dissipation base is located on the extension wall, the basal wall is perpendicular to the heat dissipation wall, the bearing surface of the heat dissipation wall is adjacent to an axis.

In some embodiments, the transistor outline packaged laser diode further comprises a plurality of pins, wherein each of the pins passes through the basal wall, each of the pins has a head section on the same side as the heat dissipation wall, and a tail section on the same side as the extension wall, the head section of each pin is located in the packaging area.

In some embodiments, the plurality of pins is divided into an upper row of pins and a lower row of pins, the lower row of pins is between the upper row of pins and the bearing surface of the heat dissipation wall.

In some embodiments, the lower row of pins is located between an axis and the bearing surface of the heat dissipation wall in the radial direction.

In some embodiments, the basal wall further has a secondary cooling surface being in the same plane as the primary cooling surface, the secondary coiling surface is used to contact the external heat dissipation element.

In some embodiments, the basal wall further has an exposed circumferential surface connected with the secondary cooling surface and both side surfaces of the basal wall, the exposed circumferential surface is in an arch shape.

In some embodiments, the extension wall further has a first peripheral surface opposite to the primary cooling surface, and at least through hole, the at least through hole connects with the primary cooling surface and the first peripheral surface.

In some embodiments, the extension wall further has a first peripheral surface opposite to the primary cooling surface, a second peripheral surface connected with the primary cooling surface and the first peripheral surface, and two through holes being arranged oppositely, the through holes connect with the primary cooling surface, the first peripheral surface and the second peripheral surface.

The present invention also provides a heat dissipation base that can be applied to the above-mentioned transistor outline packaged laser diode to enhance the effectiveness of heat dissipation.

The heat dissipation base includes a basal wall having a side surface defining a packaging area, and a heat dissipation wall extending from the side surface of the basal wall and having a bearing surface being located in the packaging area, characterized in that, the heat dissipation base further includes an extension wall extending from the other side surface of the basal wall and having a primary cooling surface for contacting an external heat dissipation element, wherein the basal wall, the heat dissipation wall and the extension wall are integrated.

### BRIEF DESCRIPTION OF THE DRAWINGS

Unless specified otherwise, the accompanying drawings illustrate aspects of the innovative subject matter described herein. Referring to the drawings, wherein like reference numerals indicate similar parts throughout the several views, several examples of transistor outline packaged laser diode incorporating aspects of the presently disclosed principles are illustrated by way of example, and not by way of limitation.

FIG. 1 illustrates a cross-section view of an embodiment of a transistor outline packaged laser diode, which is combined with a light guide unit.

FIG. 2 illustrates a perspective view of the embodiment of the transistor outline packaged laser diode.

FIG. 3 illustrates a perspective view of an embodiment of a heat dissipation base, wherein the heat dissipation base is mount on an external heat dissipation element by screw.

FIG. 4 illustrates a side view of the embodiment of the heat dissipation base.

FIG. 5 illustrates a cross-sectional view of an alternative embodiment of a transistor outline packaged laser diode, which is suitable for a printed circuit board.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings but are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

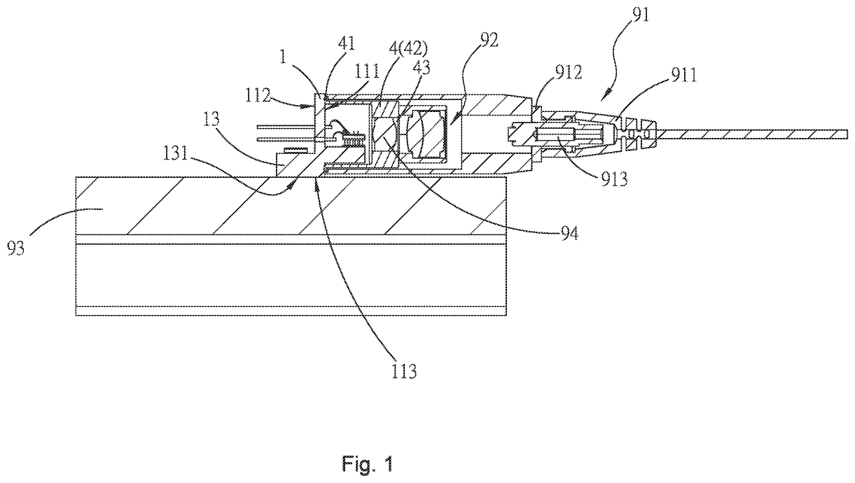

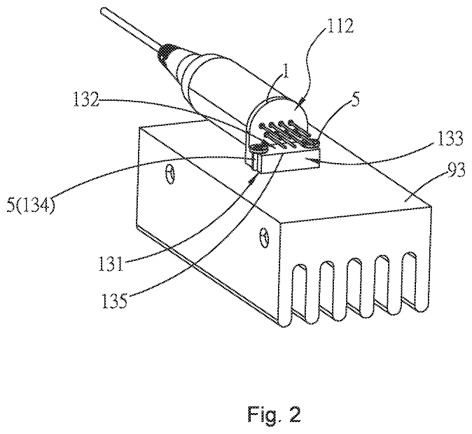

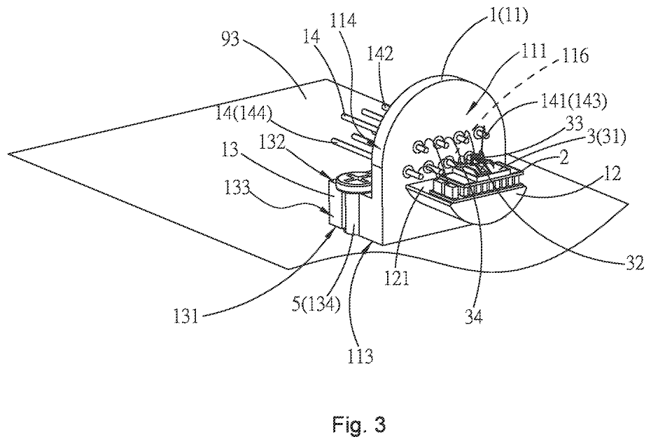

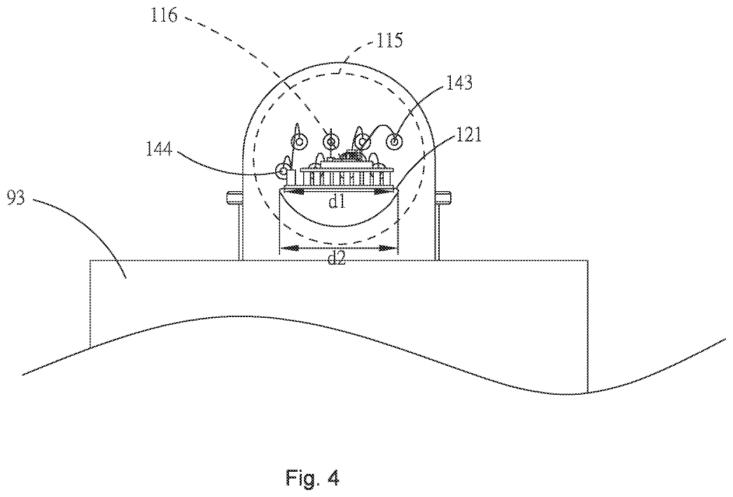

FIG. 1 illustrates a cross-section view of an embodiment of a transistor outline packaged laser diode, which is combined with a light guide unit. FIG. 2 illustrates a perspective view of the embodiment of the transistor outline packaged laser diode. FIG. 3 illustrates a perspective view of an embodiment of a heat dissipation base, wherein the heat dissipation base is mount on an external heat dissipation element by screw. FIG. 4 illustrates a side view of the embodiment of the heat dissipation base.

Referring to FIGS. 1 to 4, an embodiment of transistor outline package laser diode of the present invention is illustrated. In this embodiment, the transistor outline package laser diode can be connected to a light guide unit 91 to become a transmitting optical sub-assembly referred to as TOSA. The light guide unit 91 includes a fiber holder 911, an alignment sleeve 912, and a ferrule 913. In addition, an achromatic transmission optical sub-assembly with achromatic aberration function can be produced if an achromatic unit 92 is added.

The transistor outline packaged laser diode includes a heat dissipation base 1, a thermoelectric cooler 2, a laser sub-assembly 3, and a cover 4.

The heat dissipation base 1 includes a basal wall 11, a heat dissipation wall 12, an extension wall 13, and a plurality of pins 14. The basal wall 11, the heat dissipation wall 12 and the extension wall 13 are integrally formed, wherein the material of the heat dissipation base is a metal with high thermal conductivity, and the center of gravity of the heat dissipation base 1 is located on the extension wall 13.

The basal wall 11 includes two opposite side surfaces 111, 112, a secondary cooling surface 113, and an exposed circumferential surface 114. One of the two side surfaces defines a can-shaped packaging area 115 (as shown in FIG. 4), the exposed circumferential surface 114 is connected with the opposite side surfaces 111, 112 and the secondary cooling surface 113, the exposed circumferential surface 114 is in the shape of an arch, and the part of the exposed circumferential surface 114 away from the secondary cooling surface 113 is semicircular. The heat dissipation wall 12 extends outward from the side surface 111 of the basal wall 11 and is located in the packaging area 115. The heat dissipation wall 12 has a bearing surface 121. In this embodiment, the basal wall 11 and the heat dissipation wall 12 are perpendicular to each other, and the bearing surface 121 of the heat dissipation wall 12 is disposed adjacent to the axis 116.

The extension wall 13 extends outward from the other side surface 112 of the basal wall 11. The extension wall 13 includes a primary cooling surface 131, a first peripheral surface 132, a second peripheral surface 133 and two through holes 134. The primary cooling surface 131 is used to contact an external heat dissipation element 93, the first peripheral surface 132 is opposite to the primary cooling surface 131, and the second peripheral surface 133 is connected to the primary cooling surface 131 and the first peripheral surface 132. The two through holes 134 are arranged opposite to each other, with the two through holes 134 are respectively connected to the primary cooling surface 131, the first peripheral surface 132 and the second peripheral surface 133. Preferably, the through hole 134 is an extension hole with a semicircular cross-section. In this embodiment, the secondary cooling surface 113 of the basal wall 11 is coplanar with the primary cooling surface 131 of the extension wall 13, which contacts the external heat dissipation element 93.

The pins 14 all pass through the basal wall 11, and each pin 14 includes a head section 141 and a tail section 142. The head section 141 is located on the same side as the heat dissipation wall 12, which is arranged in the packaging area 115, and the tail section 142 is located on the same side as the extension wall 13. In this embodiment, the pins 14 are divided into the upper row of pins 143, and the lower row of pins 144 are located between the upper row of pins 143 and the bearing surface 121. Preferably, in the radial direction, the lower row of pins 144 is located between the axis 116 and the bearing surface 121.

The thermoelectric cooler 2 referred to as TEC is disposed on the bearing surface 121. Preferably, the ratio between a first width d1 of the thermoelectric cooler 2 and a second width d2 of the heat dissipation wall 12 satisfies 0.8≤d1/d2≤1 mathematical relationship, in this embodiment, d1/d2 is about 0.9. Since the pins 14 must pass through the side surface 111 of the basal wall 11, the area for mounting the thermoelectric cooler 2 on the side surface 111 of the basal wall 11 is limited, only a smaller size thermoelectric cooler can be used. In the present invention, since the thermoelectric cooler 2 is disposed on the bearing surface 121, a larger size thermoelectric cooler 2 can be used. Consequently, when the thermoelectric cooler 2 works, electrons can flow quickly over a large area at, and heat is rapidly conducted from the laser sub-assembly 3 to the heat dissipation wall 12.

The laser sub-assembly 3 is disposed on the thermoelectric cooler 2 and is electrically connected to the thermoelectric cooler 2. The laser sub-assembly 3 includes a laser submount 31, a laser chip 32, and a detector 33. The laser submount 31 is disposed on the thermoelectric cooler 2, and the laser chip 32 and the detector 33 are located on the laser submount 31. The detector 33 is used for monitoring the laser chip 32. For example, the detector 33 includes a monitor photo diode referred to as MPD, which controls the stability of the light output power of the laser chip 32 by monitoring the photocurrent change. In addition, the laser sub-assembly 3 may further include a thermistor 34 disposed on the laser submount 31, by monitoring the change of the resistance value of the thermistor 34, the thermoelectric cooler 2 is controlled to maintain the temperature setting of the laser chip 32.

The cover 4 is hollow and includes a first end portion 41 and a second end portion 42. The periphery of the first end portion 41 is correspondingly disposed on the periphery of the packaging area 115, and the second end portion 42 defines an accommodating space 43.

The following will understand the advantages of the present invention with the process of assembling and the use process:

In assembly, for example, the thermoelectric cooler 2 is firstly disposed on the bearing surface 121 of the heat dissipation base 1, and then the laser submount 31 is placed in direct contact with the thermoelectric cooler 2, the laser chip 32, the detector 33 and the thermistor 34 are disposed on the laser submount 31. The positive and negative electrodes or circuits required for the laser sub-assembly 3 and the thermoelectric cooler 2 are connected by wires (such as gold wires) to the head section 141 of the corresponding pins 14. Next, the peripheral edge of the first end portion 41 of the cover 4 is welded to the peripheral edge of the packaging area 115, and the accommodating space 43 defined by the second end portion 42 can be used for an aspheric lens 94 or a plate glass to be embedded, so that a gas-filled space is formed between the basal wall 11 and the cover 4, and the gas-filled space will be filled with nitrogen or other inert gas to protect the components from being affected by moisture, finally, the assembling process of the transistor outline packaged laser diode of the present invention is completed.

In use, the heat dissipation base 1 is mounted on the external heat dissipation element 93 through two screws 5. The screws 5 make close contact between the extension wall 13 and the external heat dissipation element 93 in order to enhance unobstructed heat conduction and provide a locking function, additionally, thermal paste or a heat dissipation pad can be applied between the extension wall 13 and the external heat dissipation element 93 as needed. Due to the two sides of the thermoelectric cooler 2 of the present invention directly contacted with the laser sub-assembly 3 and the heat dissipation wall 12 respectively, higher efficiency heat conduction can be achieved. As the laser sub-assembly 3 operates, the thermoelectric cooler 2 transfers the heat generated by the laser sub-assembly 3 across a large area to the heat dissipation wall 12. The heat dissipation wall 12, the basal wall 11 and the extension wall 13 are integrally formed, allowing for a more seamless and rapid transfer of heat to the low temperature external heat dissipation element 93 compared to the heterogeneous junction. Furthermore, the primary cooling surface 131 and the secondary cooling surface 113 of the heat dissipation base 1 are both on the same plane and in contact with the external heat dissipation element 93 over a large area, which is helpful for the external heat dissipation element 93 to quickly remove the heat from the heat dissipation base 1 to the outside.

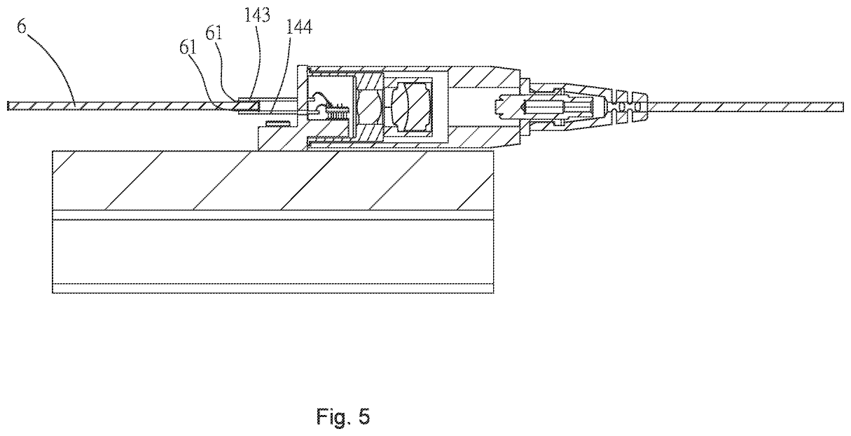

In should be noted that there can be only one through hole 134 in the extension wall 13 of the heat dissipation base 1, the single through hole can be positioned, for example, at the edge 135 of the extension wall 13 farthest from the basal wall 11 (as shown in FIG. 2) and in the middle of the edge 135. The single through hole is connected to the primary cooling surface 131 and the first peripheral surface 132, so that the same effect and purpose of the present invention can also be achieved. The pins 14 of the heat dissipation base 1 are designed as the upper row and the lower row, which is especially suitable for the printed circuit board 6 with metal pads 61 on the upper and lower sides respectively (as shown in FIG. 5), that is, the tail section 142 of the upper row of pins 143 and the tail section 142 of the lower row of pins 144 are in close contact with the metal pad 61 of the printed circuit board 6 in a clipping manner. It differs from the metal pads that only contact a small area at the end of the pins 14, the transistor outline package laser diode of the present invention allows for more efficient and faster electrical signal transmission.

The present invention not only has better heat dissipation effectiveness, but also provides the effect of firmly fixing the transmission optical sub-assembly if combined with the light guide unit.

The presently disclosed inventive concepts are not intended to be limited to the embodiments shown herein, but are to be accorded their full scope consistent with the principles underlying the disclosed concepts herein. Directions and references to an element, such as “up,” “down,”, “upper,” “lower,” “horizontal,” “vertical,” “left,” “right,” and the like, do not imply absolute relationships, positions, and/or orientations. Terms of an element, such as “first” and “second” are not literal, but, distinguishing terms. As used herein, terms “comprises” or “comprising” encompass the notions of “including” and “having” and specify the presence of elements, operations, and/or groups or combinations thereof and do not imply preclusion of the presence or addition of one or more other elements, operations and/or groups or combinations thereof. Sequence of operations do not imply absoluteness unless specifically so stated. Reference to an element in the singular, such as by use of the article “a” or “an”, is not intended to mean “one and only one” unless specifically so stated, but rather “one or more”. As used herein, “and/or” means “and” or “or”, as well as “and” and “or.” As used herein, ranges and subranges mean all ranges including whole and/or fractional values therein and language which defines or modifies ranges and subranges, such as “at least,” “greater than,” “less than,” “no more than,” and the like, mean subranges and/or an upper or lower limit. All structural and functional equivalents to the elements of the various embodiments described throughout the disclosure that are known or later come to be known to those of ordinary skill in the relevant art are intended to be encompassed by the features described and claimed herein. Moreover, nothing disclosed herein is intended to be dedicated to the public regardless of whether such disclosure may ultimately explicitly be recited in the claims. No element or concept disclosed herein or hereafter presented shall be construed under the provisions of 35 USC 112(f) unless the element or concept is expressly recited using the phrase “means for” or “step for”.

In view of the many possible embodiments to which the disclosed principles can be applied, we reserve the right to claim any and all combinations of features and acts described herein, including the right to claim all that comes within the scope and spirit of the foregoing description, as well as the combinations recited, literally and equivalently, in the following claims and any claims presented anytime throughout prosecution of this application or any application claiming benefit of or priority from this application.

What is claimed is:

1. A transistor outline packaged laser diode, comprising:
a heat dissipation base, including a basal wall, a heat dissipation wall, and an extension wall, a side surface of the basal wall defining a packaging area, the heat dissipation wall extending outward from the side of the basal wall and having a bearing surface being located in the packaging area, the extension wall extending outward from the other side surface of the basal wall and having a primary cooling surface being used to contact an external heat dissipation element, wherein the basal wall, the heat dissipation wall and the extension wall are integrated;
a thermoelectric cooler, mounted on the bearing surface of the heat dissipation wall;
a laser sub-assembly, mounted on the thermoelectric cooler and electrically connected to the thermoelectric cooler; and
a cover, being hollow and including a first end portion and a second end portion, wherein the peripheral edge of the first end portion corresponds to the peripheral edge of the packaging area and the second end portion defines an accommodating space.

2. The transistor outline packaged laser diode of claim 1, wherein the thermoelectric cooler defines a first width, the heat dissipation wall defines a second width, the first width over the second width is ranging from 0.8 to 1.

3. The transistor outline packaged laser diode of claim 1, wherein the center of gravity of the heat dissipation base is located on the extension wall, the basal wall is perpendicular to the heat dissipation wall, the bearing surface of the heat dissipation wall is adjacent to an axis.

4. The transistor outline packaged laser diode of claim 1, further including a plurality of pins, wherein each of the pins passes through the basal wall, each of the pins has a head section on the same side as the heat dissipation wall, and a tail section on the same side as the extension wall, the head section of each pin is located in the packaging area.

5. The transistor outline packaged laser diode of claim 4, wherein the plurality of pins is divided into an upper row of pins and a lower row of pins, the lower row of pins is between the upper row of pins and the bearing surface of the heat dissipation wall.

6. The transistor outline packaged laser diode of claim 5, wherein the lower row of pins is located between an axis and the bearing surface of the heat dissipation wall in the radial direction.

7. The transistor outline packaged laser diode of claim 1, wherein the basal wall further has a secondary cooling surface being in the same plane as the primary cooling surface, the secondary coiling surface is used to contact the external heat dissipation element.

8. The transistor outline packaged laser diode of claim 7, wherein the basal wall further has an exposed circumferential surface connected with the secondary cooling surface and both side surfaces of the basal wall, the exposed circumferential surface is in an arch shape.

9. The transistor outline packaged laser diode of claim 1, wherein the extension wall further has a first peripheral surface opposite to the primary cooling surface, and at least through hole, the at least through hole connects with the primary cooling surface and the first peripheral surface.

10. The transistor outline packaged laser diode of claim 1, wherein the extension wall further has a first peripheral surface opposite to the primary cooling surface, a second peripheral surface connected with the primary cooling surface and the first peripheral surface, and two through holes being arranged oppositely, the through holes connect with the primary cooling surface, the first peripheral surface and the second peripheral surface.

11. A heat dissipation base being used for a transistor outline package laser diode, the heat dissipation base including a basal wall having a side surface defining a packaging area, and a heat dissipation wall extending from the side surface of the basal wall and having a bearing surface being located in the packaging area, characterized in that:
the heat dissipation base further including an extension wall, extending from the other side surface of the basal wall and having a primary cooling surface being used to contact an external heat dissipation element, wherein the basal wall, the heat dissipation wall and the extension wall are integrated.

12. The heat dissipation base of claim 11, wherein the center of gravity of the heat dissipation base is located on the extension wall, the basal wall is perpendicular to the heat dissipation wall, the bearing surface of the heat dissipation wall is adjacent to an axis.

13. The heat dissipation base of claim 11, further including a plurality of pins, wherein each of the pins passes through the basal wall, each of the pins has a head section on the same side as the heat dissipation wall, and a tail section on the same side as the extension wall, the head section of each pin is located in the packaging area.

14. The heat dissipation base of claim 13, wherein the plurality of pins is divided into an upper row of pins and a lower row of pins, the lower row of pins is between the upper row of pins and the bearing surface of the heat dissipation wall.

15. The heat dissipation base of claim 14, wherein the lower row of pins is located between an axis and the bearing surface of the heat dissipation wall in the radial direction.

16. The heat dissipation base of claim 11, wherein the basal wall further has a secondary cooling surface being in the same plane as the primary cooling surface, the secondary coiling surface is used to contact the external heat dissipation element.

17. The heat dissipation base of claim 16, wherein the basal wall further has an exposed circumferential surface connected with the secondary cooling surface and both side surfaces of the basal wall, the exposed circumferential surface is in an arch shape.

18. The heat dissipation base of claim 11, wherein the extension wall further has a first peripheral surface opposite to the primary cooling surface, and at least through hole, the at least through hole connects with the primary cooling surface and the first peripheral surface.

19. The heat dissipation base of claim 11, wherein the extension wall further has a first peripheral surface opposite to the primary cooling surface, a second peripheral surface connected with the primary cooling surface and the first peripheral surface, and two through holes being arranged oppositely, the through holes connect with the primary cooling surface, the first peripheral surface and the second peripheral surface.
